(19) United States
(12) Patent Application Publication
(10) Pub. No.: US 2023/0084597 A1
(43) Pub. Date: Mar. 16, 2023

(54) LIGHT-EMITTING ELEMENT AND METHOD FOR MANUFATURING SAME

(71) Applicant: SHARP KABUSHIKI KAISHA, Sakai City, Osaka (JP)

(72) Inventors: Masaki YAMAMOTO, Sakai City, Osaka (JP); TADASHI KOBASHI, Sakai City, Osaka (JP)

(21) Appl. No.: 17/799,624

(22) PCT Filed: Feb. 12, 2021
(86) PCT No.: PCT/JP2021/005136

§ 371 Date: Aug. 12, 2022

(30) Foreign Application Priority Data
Mar. 3, 2020 (JP) PCT/JP2020/008808

(51) Int. Cl. H01L 51/50; H01L 51/00

(52) U.S. Cl. CPC H01L 51/502; H01L 51/5072; H01L 51/0094; H01L 51/5056; H01L 2251/303

(57) ABSTRACT

Provided is a light-emitting element having a high external quantum efficiency and a method for manufacturing the same. The light-emitting element is provided with a light-emitting layer, an electron transport layer, and an organic silicon compound. The light-emitting layer contains quantum dots. The electron transport layer is positioned on the light-emitting layer. The electron transport layer contains metal oxide particles. The organic silicon compound is positioned between the light-emitting layer and the electron transport layer. The organic silicon compound has at least one hydrocarbon group.

### TECHNICAL FIELD

The present invention relates to a light-emitting element and a method for manufacturing the same.

### BACKGROUND ART

PTL 1 describes a light-emitting element provided with a light-emitting layer containing quantum dots. The light-emitting element described in PTL 1 includes a first electrode, a second electrode, a light-emitting layer, a hole transport layer, and an electron transport layer. The first electrode and the second electrode face each other. The light-emitting layer is positioned between the first electrode and the second electrode. The light-emitting layer contains quantum dots. The hole transport layer is positioned between the first electrode and the light-emitting layer. The electron transport layer is positioned between the light-emitting layer and the second electrode.

### CITATION LIST

### Patent Literature

PTL 1: JP 2019-160796 A

### SUMMARY OF INVENTION

### Technical Problem

A demand exists for improving the external quantum efficiency (EQE) of light-emitting elements.

A main object of the present disclosure is to provide a light-emitting element having high external quantum efficiency, and a method for manufacturing the same.

### Solution to Problem

A light-emitting element according to one aspect of the present invention is provided with a light-emitting layer, an electron transport layer, and an organic silicon compound. The light-emitting layer contains quantum dots. The electron transport layer is positioned on the light-emitting layer. The electron transport layer contains metal oxide particles. The organic silicon compound is positioned between the light-emitting layer and the electron transport layer. The organic silicon compound has at least one hydrocarbon group.

A light-emitting element according to one aspect of the present invention is provided with a light-emitting layer, an electron transport layer, and an organic silicon compound. The light-emitting layer contains quantum dots. The electron transport layer is positioned on the light-emitting layer. The electron transport layer contains a metal oxide. The organic silicon compound is positioned between the light-emitting layer and the electron transport layer. The organic silicon compound has at least one hydrocarbon group.

A light-emitting element according to another aspect of the present invention is provided with a light-emitting layer, a hole transport layer, and an organic silicon compound. The light-emitting layer contains quantum dots. The hole transport layer is positioned on the light-emitting layer. The hole transport layer contains a metal oxide. The organic silicon compound is positioned between the light-emitting layer and the hole transport layer. The organic silicon compound has at least one hydrocarbon group.

In a method for manufacturing a light-emitting element according to one aspect of the present invention, a light-emitting layer containing quantum dots is formed by applying a liquid containing quantum dots. A liquid containing an organic silicon compound having at least one hydrocarbon group is applied onto the light-emitting layer. An electron transport layer containing metal oxide particles is formed by applying a liquid containing the metal oxide particles onto the light-emitting layer on which the liquid containing the organic silicon compound was applied.

In a method for manufacturing a light-emitting element according to another aspect of the present invention, a hole transport layer containing a metal oxide is formed. A liquid containing an organic silicon compound having at least one hydrocarbon group is applied onto the hole transport layer. After the liquid containing the organic silicon compound is applied, a liquid containing quantum dots is applied onto the hole transport layer, and thereby a light-emitting layer containing quantum dots is formed.

### BRIEF DESCRIPTION OF DRAWINGS

FIG. 1 is a schematic cross-sectional view of a light-emitting element according to a first embodiment.

FIG. 2 is a schematic cross-sectional view of a quantum dot of the first embodiment.

FIG. 3 is a schematic cross-sectional view in which a portion of the light-emitting element according to the first embodiment is magnified.

FIG. 4 is a schematic cross-sectional view of a light-emitting element according to a second embodiment.

FIG. 5 is a schematic cross-sectional view in which a portion of the light-emitting element according to the second embodiment is magnified.

FIG. 6 is a schematic cross-sectional view of a light-emitting element according to a third embodiment.

FIG. 7 is a schematic cross-sectional view in which a portion of the light-emitting element according to the third embodiment is magnified.

### DESCRIPTION OF EMBODIMENTS

Preferable embodiments for carrying out the present invention will be described hereinafter. However, the following embodiments are merely illustrative, and the present invention is not limited in any way to the following embodiments.

### First Embodiment

Configuration of Light-Emitting Element 1

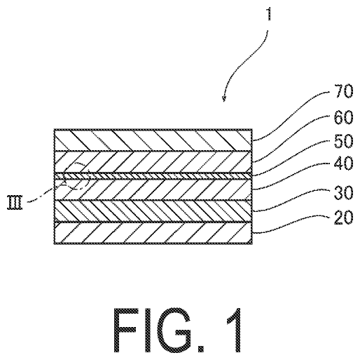

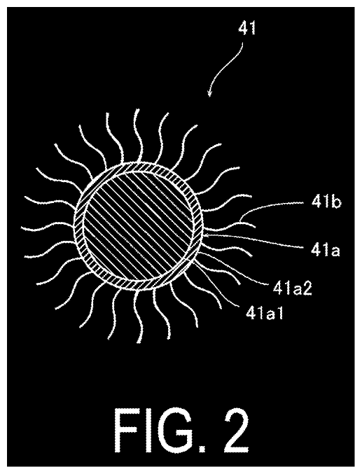

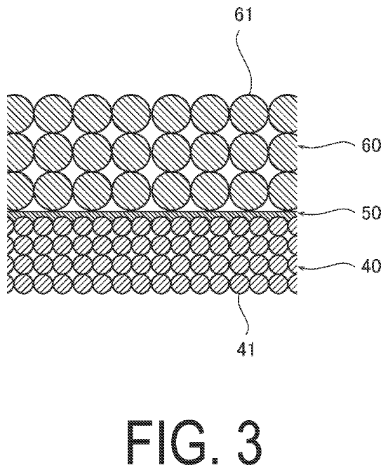

FIG. 1 is a schematic cross-sectional view of a light-emitting element 1 according to a first embodiment. FIG. 2 is a schematic cross-sectional view of a quantum dot of the first embodiment. FIG. 3 is schematic cross-sectional view in which the portion circled by the dotted line III in FIG. 1 is magnified.

The light-emitting element. 1 illustrated in FIG. 1 is a light-emitting element in which quantum dots are used. The light-emitting element 1 includes a first electrode 20, a hole transport layer 30, a light-emitting layer 40, an organic silicon compound layer 50, an electron transport layer 60, and a second electrode 70.

Ordinarily, the light-emitting element 1 is formed on a substrate (not illustrated). The substrate can be configured from, for example, an appropriate plate such as a glass plate, a ceramic plate, or a resin plate. In the light-emitting element 1, the substrate (not illustrated) may be below the first electrode 20 in 1, or may be above the second electrode 70 in FIG. 1. In a case in which the substrate is located below the first electrode 20 (anode) in FIG. 1, the light-emitting element can be stably fabricated by laminating from the anode side when fabricating the light-emitting element, and therefore the yield is improved. Furthermore, in a case in which the substrate is located above the second electrode 70 (cathode) in FIG. 1, ordinarily a transparent electrode such as an ITO electrode is adopted on the anode side of a display, and the anode side often functions as a light extraction surface. Therefore, the need for the substrate to be transparent is eliminated, the degree of freedom in substrate selection is increased, and manufacturing costs can be suppressed. Note that in the present example, a case in which the substrate is located below the first electrode 20 is described.

The first electrode 20 configures an anode that injects positive holes. The first electrode 20 can be formed of, for example, a conductive material such as a metal or a transparent conductive oxide (TCO). The first electrode 20 may be a reflective electrode or a transparent electrode. The first electrode 20 is preferably formed from a conductive material having a large work function, such as, for example, a metal, a metal oxide, or a transparent conductive oxide. Examples of metals having a large work function include Au, Ta, W, Pt, Ni, Pd, Cr, Cu, Mo, alkali metals, and alkaline earth metals. The first electrode 20 may be formed from oxides of these metals. Furthermore, examples of transparent conductive oxides having a large work function include indium tin oxide (ITO), indium zinc oxide (IZO), zinc oxide (ZnO), aluminum zinc oxide (ZnO:Al (AZO)), and boron zinc oxide (ZnO:B (BZO)). Furthermore, the first electrode 20 may be configured from, for example, a conductive polymer such as a metal-doped polythiophene, polyaniline, a polyacetylene, a polyalkylthiophene derivative, or a polysilane derivative, or α-Si or α-SiC. The first electrode 20 is preferably configured from indium tin oxide (ITO). Indium tin oxide (ITO) has a proven record of being used as a transparent electrode in many displays, and can be re-purposed for use in a manufacturing apparatus. Therefore, when the first electrode 20 is configured from ITO, manufacturing costs can be suppressed.

The second electrode 70 opposes the first electrode 20. In the present embodiment, the second electrode 70 configures a cathode that injects electrons. The second electrode 70 can be formed from, for example, a conductive material such as metal or TCO. When the first electrode 20 is a reflective electrode, the second electrode 70 is preferably a transparent electrode. When the first electrode 20 is a transparent electrode, the second electrode 70 may be a reflective electrode or a transparent electrode.

The second electrode 70 is preferably constituted from a conductive material having a smaller work function than the conductive material constituting the first electrode 20. Examples of the conductive material having a small work function include magnesium alloys such as MgAg, aluminum alloys such as AlLi, AlCa, and AlMg, alkali metals such as Li, Cs, Ba, Sr, and Ca, and alloys of alkaline earth metals. The second electrode 70 is more preferably constituted from Al or an Al alloy. Al or Al alloys are highly versatile as electrodes and are relatively inexpensive, and thus can suppress manufacturing costs.

The electrode (first electrode 20 in the present embodiment) formed on the substrate is preferably divided into pixels. Through this, when the substrate is a TFT substrate, a voltage differing from that of adjacent pixels can be applied, and thus brightness can be controlled for each pixel. Additionally, the electrode on the opposite side (second electrode 70 in the present embodiment) sandwiching the light-emitting layer 40 along with the electrode on the substrate is preferably formed so as to span a plurality of pixels. In this manner, it is not necessary to create an electrode for each pixel, and therefore the manufacturing process is simplified, and manufacturing costs can be reduced.

The light-emitting layer 40 is arranged between the first electrode 20 and the second electrode 70. The light-emitting layer 40 includes quantum dots 41 illustrated in FIG. 2, The light-emitting layer 40 may include, for example, one type of quantum dots 41, or may include a plurality of types of quantum dots 41.

Note that in the present invention, “quantum dot” means a semiconductor crystal having a quantum size effect, that is, a semiconductor particle having a particle size of 100 nm or less. Particle size means the length of the largest width portion of the particle. The semiconductor is a material formed from at least one type selected from the group consisting of at least Cd, S, Te, Se, Zn, In, N, In, As, Sb, Al, Ga, Ph, Si, Ge and Mg.

The shape of the quantum dot is not particularly restricted, and is not limited to a spherical stereoscopic shape (circular cross-sectional shape). The shape of the quantum dot may be, for example, a polygonal cross-sectional shape, a rod-shaped stereoscopic shape, a branch-shaped stereoscopic shape, or a stereoscopic shape having unevenness on the surface, or a combination thereof.

The quantum dot 41 may be configured from a semiconductor crystal (for example, a semiconductor nanocrystal) having a particle size of preferably 50 nm or less, and more preferably 30 nm or less. A peak wavelength of light emission from the quantum dot 41 depends on the particle size of the quantum dot 41. Specifically, as the particle size of the quantum dot 41 increases, the peak wavelength of light emitted from the quantum dot 41 tends to become longer. Conversely, as the particle size of the quantum dot 41 becomes smaller, the peak wavelength of light emitted from the quantum dot 41 tends to become shorter.

As illustrated in FIG. 2, the quantum dot 41 includes a semiconductor particle 41a and a ligand 41b.

In the present embodiment, the semiconductor particle 41a has a so-called core/shell structure. Specifically, the semiconductor particle 41a includes a core 41a1 and a shell 41a2. The shell 41a2 is positioned on the outer side of the core 41a1. The shell 41a2 may cover at least a portion of the outer surface of the core 41a1, In addition, the shell 41a2 may cover substantially the entire outer surface of the core 41a1, Normally, a defect is present in the shell 41a2. Thus, a portion of the outer surface of the core 41a1 may be exposed from the shell 41a2.

Note that the number of layers of the shell 41a2 is not particularly limited. The core 41a1 may be covered, for example, by a single layer of the shell 41a2, or may be covered by a laminate of a plurality of shells 41a2.

The core 41a1 and the shell 41a2 can each be configured by an appropriate semiconductor. The core 41a1 and the shell 41a2 may be configured from the same semiconductor or may be configured from different semiconductors. The core 41a1 and the shell 41a2 are each preferably configured from one or a plurality of semiconductor materials selected from the group consisting of, for example, Cd, S, Te, Se, Zn, In, N, P, As, Sb, Al, Ga, Pb, Si, Ge, Mg, and compounds thereof.

The ligand 41b is positioned at the outer side of the semiconductor particle 41a. For example, a plurality of ligands 41b may be coordinated on the semiconductor particle 41a. That is, the ligand 41b may be a ligand.

The ligand 41b is preferably, for example, an amine. Of the amines, the ligand 41b is more preferably a primary amine, is even more preferably an unsaturated amine, and is yet even more preferably an unsaturated primary amine. Specifically, the ligand 41b is preferably configured from, for example, oleylamine ((9Z)-9-octadecen-1-amine). Since the oleylamine has an amino group, the bonding force of the oleylamine to the surface of the semiconductor particle 41a is strong, and thus it is thought that the surface of the semiconductor particle 41a can be suitably protected by using oleylamine as the ligand 41b. Furthermore, since the oleylamine has a long alkyl group, dispersibility of the quantum dots 41 into an organic solvent can be improved by using the oleylamine as the ligand 41b, and the stable presence of the quantum dots 41 in the organic solvent can be facilitated.

The hole transport layer 30 is arranged between the light-emitting layer 40 and the first electrode 20, and the electron transport layer 60 is arranged between the light-emitting layer 40 and the second electrode 70.

The hole transport layer 30 is arranged between the first electrode 20 and the light-emitting, layer 40. The hole transport layer 30 is formed on the first electrode 20. The hole transport layer 30 is a layer that transports positive holes injected from the first electrode 20 to the light-emitting layer 40. The hole transport layer 30 may have a so-called electron-blocking function of suppressing the transport of electrons to the first electrode 20. Note that in the present invention, the hole transport layer is not necessarily an essential configurational requirement.

The hole transport layer 30 includes a hole transport material. Examples of such hole transport materials include arylamine derivatives, anthracene derivatives, carbazole derivatives, thiophene derivatives, fluorene derivatives, distyrylbenzene derivatives, and spiro compounds. Note that the material used in the hole transport layer 30 is more preferably polyvinyl carbazole (PVK) or poly[(9,9-dioctylfluorenyl-2,7-diyl)-co-(4,4′-(N-(4-sec-butylphenyl)) diphenyl amine)] (TFB), The PVK and the TFB improve the efficiency of light emission through a recombination of the electrons and the positive holes in the quantum dot light-emitting layer, and thus can improve the light-emission characteristics of the light-emitting element.

A hole injection layer (not illustrated) that injects positive holes may be formed between the first electrode 20 and the light-emitting layer 40. Note that if a hole injection layer and the hole transport layer 30 are formed, the hole injection layer and the hole transport layer are preferably laminated such that the hole injection layer is positioned further to the first electrode 20 side than the hole transport layer.

Also note that the hole injection layer includes a hole injection material. Examples of the hole injection material include conductive polymers such as arylamine derivatives, porphyrin derivatives, phthalocyanine derivatives, carbazole derivatives, polyaniline derivatives, polythiophene derivatives, and polyphenylene vinylene derivatives.

The material used in the hole injection layer is more preferably poly(3,4-ethylenedioxythiophene)-polystyrene sulfonate (PEDOT-PSS). The PEDOT-PSS improves the efficiency of light emission through a recombination of the electrons and the positive holes in the quantum dot light-emitting layer, and thus can improve the light-emission characteristics of the light-emitting element.

The electron transport layer 60 is arranged between the light-emitting layer 40 and the second electrode 70. The electron transport layer 60 is formed on the light-emitting layer 40. The electron transport layer 60 is a layer that transports electrons injected from the second electrode 70 to the light-emitting layer 40. Further, the electron transport layer 60 may have a so-called hole blocking function of suppressing the transport of positive holes to the second electrode 70.

The electron transport layer 60 includes metal oxide particles containing a metal oxide. The metal oxide functions as an electron transport material. The energy level of a lower end of a conduction band of the metal oxide is preferably less than or equal to the energy level of a lower end of a conduction band of the quantum dots 41. This is because when the electron affinity of the electron transport layer 60 is smaller than the electron affinity of the quantum dots 41, a triangular potential due to heterojunctions between the metal oxide and the quantum dots occurs, but according to the configuration described above, the effect of the triangular potential due to the heterojunctions between the metal oxide and the quantum dots can be reduced, and a light-emitting element having a high luminous efficiency can be realized.

The metal oxide preferably contains at least one of, for example. In, Zn and Sn. Specific examples of the metal oxides that are preferably used include ZnO, InGaZnO (IGZO), TiO₂, Ta₂O₃, SrTiO₃, and MgₓZn₍₁₋ₓ₎O (where x is the ratio of the Zn of ZnO substituted with Mg). Among these, IGZO is more preferably used as the metal oxide. This is because use of IGZO simplifies control of the carrier density by controlling the composition ratio, and therefore an electron transport layer suitable for the light emission wavelength of the quantum dot light-emitting layer can be easily prepared.

Note that in the present invention, a plurality of metal oxide particles may be dispersed in a medium and may exist independently of each other, or a plurality of metal oxide particles may be bonded and integrated through the grain boundaries. The layer containing metal oxide particles may be, for example, a layer of a metal oxide in which the plurality of metal oxide particles are sintered and thereby bonded through the grain boundaries.

An electron injection layer (not illustrated) that injects electrons may be formed between the second electrode 70 and the electron transport layer 60.

The electron injection layer contains an electron injection material. Examples of the electron injection material include alkali metals or alkaline earth metals, oxides of alkali metals or alkaline earth metals, fluorides of alkali metals or alkaline earth metals, and organic complexes of alkali metals, such as aluminum, strontium, calcium, lithium, cesium, magnesium oxide, aluminum oxide, strontium oxide, lithium oxide, lithium fluoride, magnesium fluoride, strontium fluoride, calcium fluoride, barium fluoride, cesium fluoride, and sodium polymethylmethacrylate polystyrene sulfonate.

An organic silicon compound is positioned between the light-emitting layer 40 and the electron transport layer 60. Specifically, in the present embodiment, an organic silicon compound layer 50 containing an organic silicon compound is positioned between the light-emitting layer 40 and the electron transport layer 60. The organic silicon compound layer 50 and the hole transport layer 30 configuring the hole transport layer are isolated by the light-emitting layer 40.

More specifically, in the present embodiment, as illustrated in FIG. 3, the organic silicon compound is positioned on, of the plurality of quantum dots 41 constituting the light-emitting layer 40, the quantum dots 41 exposed at the surface of the light-emitting layer 40 on the electron transport layer 60 side. The organic silicon compound is not included in the central portion in the thickness direction of the light-emitting layer 40, In the present embodiment, substantially the entire light-emitting layer 40 does not include the organic silicon compound.

Note that in the present invention, the expression that “the central portion in the thickness direction of the light-emitting layer does not contain the organic silicon compound” is intended to mean that the concentration of the organic silicon compound at the central portion in the thickness direction of the light-emitting layer is less than or equal to a detection limit at a line segment that traverses a cut surface in a direction perpendicular to the light-emitting layer surface, the line segment being arbitrarily selected on the cut surface exposed by cutting the light-emitting layer along the direction perpendicular to the light-emitting layer surface. In other words, in a case in which the organic silicon compound is not detected at a concentration higher than the detection limit from a central portion in the thickness direction of the light-emitting layer at a line segment traversing a cut surface in a direction perpendicular to the light-emitting layer surface, the line segment being arbitrarily selected on the cut surface exposed by cutting the light-emitting layer along the direction perpendicular to the light-emitting layer surface, the “central portion in the thickness direction of the light-emitting layer does not contain the organic silicon compound”.

Similarly, in the present invention, the expression that “the light-emitting layer does not contain an organic silicon compound” means that on a line segment traversing a. cut surface in a direction perpendicular to the light-emitting layer surface, the line segment being arbitrarily selected on the cut surface exposed when the light-emitting layer is cut along the direction perpendicular to the light-emitting layer surface, the concentration of the organic silicon compound along the line segment from a quantum dot located at a furthest end of one end point side of the line segment to a quantum dot at the furthest end of the other end point side of the line segment is less than or equal to the detection limit. In other words, in a case in which, on a line segment traversing a cut surface in a direction perpendicular to the light-emitting layer surface, the line segment being arbitrarily selected on the cut surface exposed when the light-emitting layer is cut along the direction perpendicular to the light-emitting layer surface, the organic silicon compound is not detected at a concentration higher than the detection limit along the line segment from a quantum dot located at the furthest end of one end point side of the line segment to a quantum dot at the furthest end of the other end point side of the line segment, “the light-emitting layer does not contain the organic silicon compound.”

Note that the detection limit of the concentration of the organic silicon compound is, for example, 0.1 at %.

Note that the “central portion in the thickness direction of the light-emitting layer” is intended to mean a portion positioned in a range from the center of a line segment to ±10% of a length (L0) of the line segment, the line segment traversing a cut surface in a direction perpendicular to the light-emitting layer surface and being arbitrarily selected on the cut surface that is exposed when the light-emitting layer is cut along the direction perpendicular to the light-emitting layer surface.

The organic silicon compound is not particularly limited as long as it is a compound having a Si (silicon) to which at least one hydrocarbon group is bonded, and among such organic silicon compounds, an organic silicon compound for which each of four functional groups bonded to the Si is an organic group is more preferably used. Furthermore, an organic silicon compound for which the four functional groups bonded to Si include a saturated or unsaturated hydrocarbon group having from 1 to 30 carbons is more preferably used. An organic silicon compound in which the four functional groups bonded to Si include a chain hydrocarbon group is more preferably used. Moreover, an organic silicon compound in which the four functional groups bonded to Si include at least one of an alkoxyl group and an acetyl group is more preferably used. Through this, the improvement in external quantum efficiency becomes more remarkable. An organic silicon compound in which one of the four functional groups bonded to Si is a hydrocarbon group, and the other three functional groups are each an alkoxyl group or an acetyl group is more preferably used.

Note that in the present invention, the hydrocarbon group is preferably a substituent constituted only of carbon and hydrogen. The hydrocarbon group is preferably a substituent that is constituted of only carbon and hydrogen and does not include a heteroatom such as oxygen or nitrogen.

As a result of diligent research, the present inventors discovered that the external quantum efficiency (EQE) of the light-emitting element 1 can be improved by positioning, between the light-emitting layer 40 and the electron transport layer 60, an organic silicon compound having at least one hydrocarbon group, and thereby conceived of the light-emitting element 1 according to the present embodiment. That is, in the light-emitting element 1, an organic silicon compound having at least one hydrocarbon group is positioned between the light-emitting layer 40 and the electron transport layer 60. Thus, high external quantum efficiency can be realized according to the light-emitting element 1.

Improvement in the external quantum efficiency of the light-emitting element 1 by positioning the organic silicon compound between the light-emitting layer 40 and the electron transport layer 60 is not due to an improvement in wettability (described in detail below), but rather, is thought to be due to the following reason. That is, it is thought that a current path is formed from the electron transport layer 60 to the light-emitting layer 40 by positioning, between the light-emitting layer 40 and the electron transport layer 60, an organic silicon compound having at least one hydrocarbon group bonded thereto, and thus the efficiency at which carriers (electrons) are injected into the light-emitting layer 40 from the electron transport layer 60 is improved.

The organic silicon compound need not necessarily be provided in a layered manner between the light-emitting layer 40 and the electron transport layer 60. However, from the perspective of further improving the external quantum efficiency of the light-emitting element 1, the organic silicon compound layer 50 including the organic silicon compound is more preferably arranged between the light-emitting layer 40 and the electron transport layer 60.

The thickness of the organic silicon compound layer 50 is, for example, preferably from 0.1 nm to 5 nm. When the organic silicon compound layer 50 is too thin, the effect of improving the external quantum efficiency may not be sufficiently obtained. When the organic silicon compound layer 50 is too thick, the efficiency of electron injection into the light-emitting layer 40 may decrease. Here, the thickness of the organic silicon compound layer means the maximum thickness of the organic silicon compound layer at any cut surface obtained by cutting the organic silicon compound layer along the thickness direction of the organic silicon compound layer. The thickness of the organic silicon compound layer can be measured, for example, by observing a cross-section of the organic silicon compound layer using a scanning electron microscope (SEM), a transmission electron microscope (TEM), or the like. Note that it is not necessary that the thickness of the organic silicon compound layer 50 be uniform. The organic silicon compound layer 50 may have thickness unevenness. The organic silicon compound layer 50 may include a relatively thick portion and a relatively thin portion.

Note that in the present invention, it is not necessary that the organic silicon compound layer be provided in an entire region where the light-emitting layer and the electron transport layer or the hole transport layer overlap. The organic silicon compound layer need not cover the entire surface of the light-emitting layer. The organic silicon compound layer includes those formed in a layered manner on at least a part of a region where the light-emitting layer and the electron transport layer or the hole transport layer overlap. Accordingly, even when the organic silicon compound layer is provided, there may be a case in which the organic silicon compound layer is not interposed between the light-emitting layer and the electron transport layer or the hole transport layer, and thus a portion may be present at which the light-emitting layer and the electron transport layer or the hole transport layer are opposing without the organic silicon compound layer being interposed therebetween.

Specifically, the organic silicon compound layer may be configured, for example, from a plurality of island-shaped organic silicon compound layers provided between the light-emitting layer and the electron transport layer or the hole transport layer. Furthermore, for example, a plurality of through-holes penetrating along the thickness direction may be formed in the organic silicon compound layer.

In any cross-section along the thickness direction of the light-emitting element 1, the organic silicon compound layer covers preferably 10% or more, more preferably 30% or more, even more preferably 50% or more, yet even more preferably 70% or more, still even more preferably 90% or more, and most preferably 100% of the surface of the hole transport layer. Note that the matter of covers 100% here means that a portion continuously covering 1 μm in terms of the width in a direction perpendicular to the thickness direction is present. That is, to satisfy the above numeric percentage values, it is sufficient to measure the width in a 1 μm range in a direction perpendicular to the thickness direction of the organic silicon compound layer and know that the numeric percentage values are satisfied.

Additionally, the organic silicon compound layer need not have a substantially, uniform thickness, and the organic silicon compound layer may have thickness unevenness.

From the perspective of improving the external quantum efficiency of the light-emitting element 1, the organic silicon compound is preferably arranged between the light-emitting layer 40 and the electron transport layer 60 constituting the electron transport layer. The organic silicon compound and the hole transport layer 30 are more preferably isolated by the light-emitting layer 40.

Furthermore, the organic silicon compound is preferably not included in the central portion of the light-emitting layer 40 in the thickness direction, is more preferably not included in substantially the entire light-emitting layer 40, and is even more preferably not included in the light-emitting layer 40. This is because in such a case, a decrease in carrier injection efficiency due to an organic silicon compound having relatively poor electrical conductivity can be suppressed.

Furthermore, the four functional groups bonded to Si in the organic silicon compound are each preferably an organic group. In the organic silicon compound, the four functional groups bonded to Si preferably include a saturated or unsaturated. hydrocarbon group having from 1 to 30 carbons. The number of carbons of the saturated or unsaturated hydrocarbon group is more preferably from 3 to 20, and even more preferably from 5 to 15. When the number of carbons is 15 or less, the carbon chain is short, and therefore the current path to the electron transport layer from the quantum dot layer presumed to be the source of improvements in EQE is shorter, and thus it is thought that the EQE improvement effect becomes clearer.

The four functional groups bonded to Si in the organic silicon compound preferably include a chain hydrocarbon group. The four functional groups bonded to Si in the organic silicon compound preferably include at least one of an alkoxyl group and an acetyl group. Specific examples of the alkoxyl group include, for example, a methoxy group, an ethoxy group, a propoxy group, and a butoxy group, and of these, a methoxy group, which has a short carbon chain, is more preferable as the alkoxyl group. Through this, since the methoxy group has a relatively short carbon chain, the current path from the quantum dot layer presumed to be the source of improvements in EQE to the electron transport layer becomes shorter, and thus it is thought that the EQE improvement effect becomes clearer.

More preferably, one of the four functional groups bonded to Si in the organic silicon compound is a hydrocarbon group, and the other three functional groups are each an alkoxyl group and/or an acetyl group. When an electron transport layer containing metal oxide nanoparticles is prepared through application onto a light-emitting layer containing quantum dots, a new problem occurs. That is, the external quantum efficiency, which indicates the light-emission characteristics of an essential element, worsens even with an improvement in wettability. However, when one of the four functional groups bonded to Si in the organic silicon compound is a hydrocarbon group, and the other three functional groups are each an alkoxyl group or an acetyl group, the external quantum efficiency, which indicates the light-emission characteristics of the element, can be improved without worsening. Examples of the hydrocarbon group include alkyl groups, such as a methyl group and an ethyl group, and an phenyl group, which is an aromatic group. Among these, an octadecyl group is more preferable as the hydrocarbon group. Since the octadecyl group is often used as a hydrophobic functional group, the material cost of the silane coupling agent can be suppressed.

Furthermore, the hydrocarbon group contained in the organic silicon compound is preferably a fluorine-based functional group such as an alkyl fluoride group. Since the fluorine-based functional group includes fluorine, the fluorine-based functional group is a hydrophobic group, and thus, the range of choices for the material constituting the hydrocarbon group having hydrophobic properties is widened, and material design is simplified.

Note that the presence of fluorine can be detected by implementing elemental analysis through TEM-EDX or SPS.

From the perspective of improving the external quantum efficiency of the light-emitting element 1, each of the quantum dots 41 included in the light-emitting layer 40 preferably includes a ligand 41b positioned on the outer side of the semiconductor particle 41a. This is because in this case, it is thought that the affinity between the quantum dot 41 and the hydrocarbon group of the organic silicon compound improves, and as a result, it is thought that the external quantum efficiency of the light-emitting element 1 can be further improved.

From the viewpoint of further improving the external quantum efficiency, the ligand 41b is preferably an amine, and more preferably a primary amine. Additionally, the ligand 41b is preferably an unsaturated amine. Specifically, the ligand 41b is preferably, oleylamine, for example. The oleylamine has an amino group, and therefore bonding to the quantum dot surface is strong, and strong surface protection can be achieved.

Furthermore, since the oleylamine has a long alkyl group, dispersibility in an organic solvent can be improved by using the oleylamine as the ligand 41b, and thereby the quantum dots can be stably present in the solution.

From the perspective of improving the external quantum efficiency of the light-emitting element 1, the metal oxide contained in the electron transport layer 60 preferably includes at least one material selected from In, Zn, and Sn. Specifically, the metal oxide contained in the electron transport layer 60 is preferably, for example, ZnO, InGaZnO (IGZO), TiO₂, Ta₂O₃, SrTiO₃, or MgₓZn₍₁₋ₓ₎O (where x is the ratio of the Zn of ZnO substituted with Mg), and of these, the metal oxide is more preferably IGZO.

From the perspective of further improving the external quantum efficiency of the light-emitting element 1, the energy level at the lower end of the conduction band of the metal oxide included in the electron transport layer 60 is preferably less than or equal to the energy level at the lower end of the conduction band of the quantum dots 41. In this case, the effect of forming a triangular potential due to the formation of heterojunctions between the metal oxide and the quantum dots 41 can be reduced. Accordingly, it is thought that the external quantum efficiency of the light-emitting element 1 can be further improved.

From the perspective of further improving the external quantum efficiency of the light-emitting element 1, the electron affinity of the electron transport layer 60 constituting the electron transport layer is preferably greater than the electron affinity of the light-emitting layer 40. In this case, the effect of forming a triangular potential due to the formation of heterojunctions between the metal oxide and the quantum dots 41 can be reduced. Accordingly, it is thought that the external quantum efficiency of the light-emitting element 1 can be further improved.

Note that the external quantum efficiency (EQE) is the efficiency obtained in consideration of the light-extraction efficiency in the internal quantum efficiency (IQE). The internal quantum efficiency refers to the percentage of photons produced in relation to the number of electrons injected and recombined. The light-extraction efficiency refers to the percentage of the number of photons emitted outside of the light-emitting element relative to the number of photons generated in the light-emitting element.

### Method for Manufacturing Light-Emitting Element 1

The method for manufacturing the light-emitting element 1 is not particularly limited. The light-emitting element 1 can be manufactured, for example, as outlined below.

First, the first electrode 20 is formed on a substrate. The first electrode 20 can be formed, for example, through a method such as physical vapor deposition (PVD) or chemical vapor deposition (CVD). A specific example of the PVD method includes a sputtering method.

Next, the hole transport layer 30 is formed on the first electrode 20. For example, the hole transport layer 30 can be formed as outlined below. First, a dispersion liquid in which a hole transport material such as, for example, poly(3,4-ethylenedioxythiophene):poly(styrene sulfonic acid) (PEDOT:PSS) is dispersed is prepared. The dispersion liquid can be applied onto the first electrode 20 and dried to form the hole transport layer 30.

Next, a light-emitting layer 40 is formed on the hole transport layer 30. For example, a liquid (for example, a colloidal solution) containing quantum dots 41 can be applied onto the hole transport layer 30 and dried to thereby form the light-emitting layer 40.

Next, a liquid containing an organic silicon compound having at least one hydrocarbon group is applied onto the light-emitting layer 40 and dried to thereby arrange the organic silicon compound on the light-emitting layer 40. An organic silicon compound layer containing the organic silicon compound may be formed on the light-emitting layer 40, or a liquid containing the organic silicon compound may be applied onto the light-emitting layer 40 such that the organic silicon compound is partially adhered onto the surface of the light-emitting layer 40.

Note that the concentration of the organic silicon compound in the liquid containing the organic silicon compound is preferably from 0.1 mass % to 50 mass %. When the concentration of the organic silicon compound is too low, the EQE improvement effect may be insufficient. If the concentration of the organic silicon compound is too high, the viscosity of the liquid containing the organic silicon compound becomes high, and it may be difficult to stably prepare the organic silicon compound layer. The concentration of the organic silicon compound is more preferably from 0.15 mass % to 30 mass %, and even more preferably from 0.2 mass % to 10 mass %. The organic silicon compound can be suitably arranged on the light-emitting layer 40 by setting the concentration of the organic silicon compound in the liquid containing the organic silicon compound to the range described above.

Next, a liquid containing metal oxide particles is applied onto the light-emitting layer 40 on which the organic silicon compound was arranged, and then dried to form the electron transport layer 60.

Next, the second electrode 70 is formed on the electron transport layer 60. The second electrode 70 can be formed by, for example, the PVD method or the CVD method.

According to the manufacturing method described above, a light-emitting element 1 having high external quantum efficiency can be suitably manufactured.

In the first embodiment, an example was described in which an organic silicon compound is arranged between the light-emitting layer 40 and the electron transport layer 60. However, the present invention is not limited to such configurations.

As long as the organic silicon compound is arranged between a light-emitting layer and a charge transport layer containing a metal oxide, the external quantum efficiency of light emission can be improved in any case in which the organic silicon compound is arranged between the light-emitting layer and any type of charge transport layer. In a case in which a plurality of charge transport layers are provided adjacent to the light-emitting layer, the organic silicon compound may be arranged between all of the charge transport layers and the light-emitting layer, or the organic silicon compound may, be arranged between some of the charge transport layers and the light-emitting layer.

Another preferable embodiment for carrying out the present invention will be described hereinafter. In the following description, members having substantially the same functions as those of the first embodiment are referenced by the same reference sign, and the explanations in the first embodiment are incorporated by reference.

### Second Embodiment

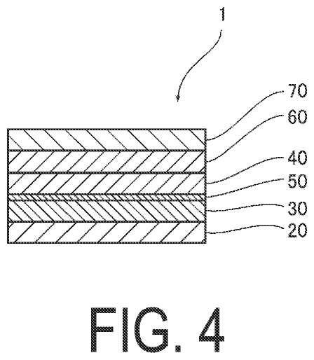

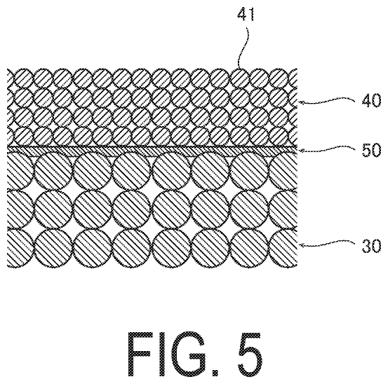

FIG. 4 is a schematic cross-sectional view of a light-emitting element 1a according to a second embodiment. FIG. 5 is a schematic cross-sectional view in which a portion of the light-emitting element 1a according to the second embodiment is magnified.

In the second embodiment, an example is described in which an organic silicon compound is positioned between a light-emitting layer and a hole transport layer containing a metal oxide. Hereinafter, only those portions differing from the first embodiment are described, and for the other portions, the explanations given in the first embodiment are incorporated by reference.

As illustrated in FIGS. 4 and 5, in the light-emitting element 1a according to the second embodiment, an organic silicon compound is arranged between the hole transport layer 30 and the light-emitting layer 40. Specifically, an organic silicon compound layer 60 is arranged between the hole transport layer 30 and the light-emitting layer 40. In the second embodiment, the organic silicon compound is substantially not disposed between the light-emitting layer 40 and the electron transport layer 60.

The hole transport layer 30 in the second embodiment contains a metal oxide. The hole transport layer 30 preferably includes the metal oxide as a hole transport material. That is, the metal oxide preferably functions as a hole transport material.

Examples of metal oxides that function as hole transport materials include oxides of at least one type of metal selected from the group consisting of Zn, Cr, Ni, Ti, Nb, Al, Si, Mg, Ta, Hf, Zr, Y, La, and Sr. Specific examples of metal oxides that function as hole transport materials include, for example, NiO, MgO, MgNiO, LaNiO₃, CuO, and Cu₂O. Of these, NiO is more preferably used.

In the present embodiment, the organic silicon compound is arranged between the light-emitting layer 40 and the hole transport layer 30 containing the metal oxide. Thus, the external quantum efficiency of the light-emitting element 1a can be improved. Although the reason for this is not clear, it is thought that the improvement occurs because when an organic silicon compound having at least one hydrocarbon group bonded thereto is positioned between the light-emitting layer 40 and the hole transport layer 30 containing the metal oxide, a current path is formed between the hole transport layer 30 and the light-emitting layer 40, and thus the efficiency of injecting carriers (positive holes) into the light-emitting layer 40 from the hole transport layer 30 is improved.

The organic silicon compound is not required to be provided in a layered manner between the light-emitting layer 40 and the hole transport layer 30. However, from the perspective of further improving the external quantum efficiency of the light-emitting element 1a, the organic silicon compound layer 50 including the organic silicon compound is more preferably arranged between the light-emitting layer 40 and the hole transport layer 30.

In the second embodiment, the electron transport layer 60 is not necessarily an essential configurational requirement. Also, the electron transport layer 60 need not contain a metal oxide.

### Method for Manufacturing Light-Emitting Element 1a

Next, of an example of a method for manufacturing the light-emitting element 1a, those points differing from the example of the method for manufacturing the light-emitting element 1 described in the first embodiment are described below.

In the second embodiment, the hole transport layer 30 including the metal oxide is formed on the first electrode 20. For example, a hole transport layer 30 containing NiO can be formed by applying a liquid containing NiO particles onto the first electrode 20 and then drying. Furthermore, the hole transport layer 30 can also be formed by applying a liquid containing nickel oxide or a NiO precursor such as nickel acetylacetonate onto the first electrode 20 and then baking.

Specifically, the hole transport layer 30 containing NiO can be formed, for example, as outlined below.

The hole transport layer 30 can be formed by first preparing a dispersion liquid in which NiO particles are dispersed in ethanol, and then next, applying the dispersion onto the first electrode 20 and drying, and then baking at 230° C. in the air.

### Third Embodiment

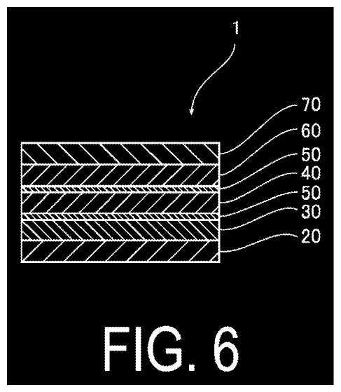

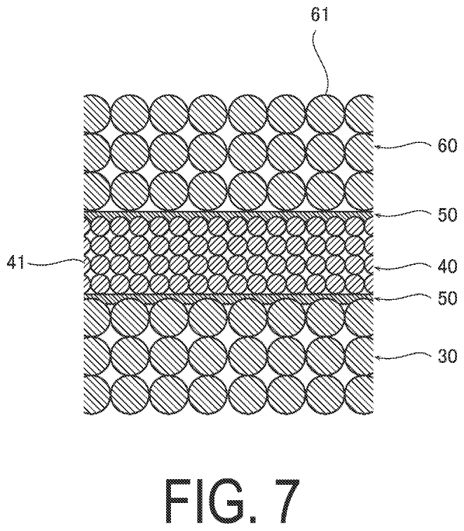

FIG. 6 is a schematic cross-sectional view of a light-emitting element 1b according to a third embodiment. FIG. 7 is a schematic cross-sectional view in which a portion of the light-emitting element 1b according to the third embodiment is magnified.

In the first embodiment and the second embodiment, examples were described in which an organic silicon compound was arranged between the light-emitting layer 40 and the hole transport layer 30, or between the light-emitting layer 40 and the electron transport layer 60.

However, the present invention is not limited to such configurations. For example, the organic silicon compound may be arranged between the hole transport layer 30 and the light-emitting layer 40, and between the light-emitting layer 40 and the electron transport layer 60.

As illustrated in FIGS. 6 and 7, in the light-emitting element 1b according to the third embodiment, the hole transport layer 30 and the electron transport layer 60 both include a metal oxide.

The hole transport layer 30 preferably includes, for example, a metal oxide that functions as the hole transport material exemplified in the second embodiment.

The electron transport layer 60 preferably includes, for example, a metal oxide that functions as the electron transport material exemplified in the first embodiment.

In the present embodiment, an organic silicon compound is arranged between the light-emitting layer 40 and the hole transport layer 30 containing the metal oxide, and between the light-emitting layer 40 and the electron transport layer 60 containing the metal oxide. Specifically, an organic silicon compound layer 50 is arranged between the light-emitting layer 40 and the hole transport layer 30 containing the metal oxide, and between the light-emitting layer 40 and the electron transport layer 60 containing the metal oxide. Thus, the external quantum efficiency of the light-emitting element 1b can be further improved.

### Example 1

A sample of a light-emitting element according to Example 1 was prepared as outlined below.

First, a first electrode formed from indium tin oxide TO) was formed on a substrate through sputtering.

Next, a hole injection layer was formed on the first electrode by applying an aqueous solution of PEDOT:PSS onto the first electrode through spin coating.

Next, a hole transport layer was formed on the hole injection layer by applying a chlorobenzene solution of polyvinyl carbazole onto the hole injection layer through spin coating.

Next, a light-emitting layer was formed on the hole transport layer in the following manner. First, toluene was removed from a quantum dot solution (NP-620, available from NN-Labs) of an InP/ZnS material by centrifugal separation, and the quantum dots were dispersed in hexane to prepare a dispersion liquid. The dispersion liquid was applied onto the hole transport layer through spin coating at a rotational speed of 2000 rpm, and then heated at 80° C. in air to form a light-emitting layer.

An amount of 0.008 g of octadecyltrimethoxysilane, 4.76 g of ethanol, and 0.25 g of pure water were mixed for 12 hours. The obtained mixture (0.2 mass %) was applied onto the light-emitting layer through spin coating at a rotational speed of 4000 rpm, and heated at 80° C.

Next, ZnO nanoparticle ink obtained by dispersing ZnO particles in isopropyl alcohol was applied by ink jetting and then baked at 80° C. in air, and an electron transport layer was thereby formed.

Next, a second electrode made of aluminum was formed by vapor deposition, and a sample of the light-emitting element according to Example 1 was prepared.

In addition, 1 μL of the ZnO nanoparticle ink obtained by dispersing ZnO particles in isopropyl alcohol was dripped onto the light-emitting layer treated with octadecyltrimethoxysilane, and the contact angle was measured. The results are shown in Table 1.

### Comparative Example 1

A sample of a light-emitting element according to Comparative Example 1 was prepared in the same manner as in Example 1 with the exception that the liquid containing octadecyltrimethoxysilane was not applied onto the light-emitting layer.

In addition, 1 μL, of a ZnO nanoparticle ink obtained by dispersing ZnO particles in isopropyl alcohol was dripped onto the light-emitting layer not treated with octadecyltrimethoxysilane, and the contact angle was measured. The results are shown in Table 1.

### Comparative Example 2

A sample of a light-emitting element according to Comparative Example 2 was prepared in the same manner as in Example 1 with the exception that 3-aminopropyltrimethoxysilane (available from JNC Corporation) was used instead of octadecyltrimethoxysilane.

Note that the 3-aminopropyl group and the methoxy group are both substituents containing a hetero element, and thus 3-aminopropyltrimethoxysilane is an organic silicon compound that does not have a hydrocarbon group.

In addition, 1 μL of the ZnO nanoparticle ink obtained by dispersing ZnO particles in isopropyl alcohol was dripped onto the light-emitting layer treated with 3-aminopropyltrimethoxysilane, and the contact angle was measured. The results are shown in Table 1.

### Evaluation

The samples of light-emitting elements prepared in Example 1, Comparative Example 1, and Comparative Example 2 were each subjected to WI, measurements, and the external quantum efficiency (EQE) was calculated from the results. The results are shown in Table 1.

TABLE 1

| | | EQE | Contact |
|---|---|---|---|
| | Organic Silicon Compound | (%) | Angle |
| Example 1 | Octadecyltrimethoxysilane | 6.6 | 38° |
| Comparative example 1 | (none) | 5.6 | 37° |
| Comparative example 2 | 3- | 3.6 | 22° |
| | aminopropyltrimethoxysilane | | |

From the results shown in Table 1, it is clear that the sample according to Example 1 in which the organic silicon compound having at least one hydrocarbon group is disposed between the light-emitting layer and the electron transport layer has a contact angle that is approximately equivalent to that of the sample according to Comparative Example 1, which does not contain the organic silicon compound. That is, while the two samples exhibit nearly equivalent wettability, the sample according to Example 1 has a higher external quantum efficiency than the sample according to Comparative Example 1. In addition, the contact angle of the sample according to Comparative Example 2, in which an organic silicon compound not having a hydrocarbon group is arranged between the light-emitting layer and the electron transport layer, is smaller than the contact angle of the sample according to Comparative Example 1. In other words, wettability is improved in Comparative Example 2, but an improvement in external quantum efficiency was not observed, and the external quantum efficiency was lower than that of Comparative Example 1. From this, it is clear that in order to improve the external quantum efficiency, an organic silicon compound having at least one hydrocarbon group must be arranged between the light-emitting layer and the electron transport layer. As described above, when an electron transport layer containing metal oxide nanoparticles was prepared through application onto a light-emitting layer containing quantum dots, a new problem was discovered. That is, the external quantum efficiency, which indicates the light-emission characteristics of an essential element, worsens even with an improvement in wettability. However, a new effect was discovered by adopting the configuration of the present application, namely, the external quantum efficiency, which indicates the light-emission characteristics of an element, can be improved without worsening.

### Example 2

A sample of a light-emitting element according to Example 2 was prepared as outlined below.

First, a first electrode formed from indium tin oxide (ITO) was formed in the same manner as in Example 1.

Next, a dispersion liquid in which NiO particles were dispersed in ethanol was prepared. The dispersion liquid was applied onto the first electrode 20 and dried, and then baked at 230° C. in the air to thereby form a hole transport layer.

Next, an organic silicon compound layer, a light-emitting layer 40, and an electron transport layer were each formed in the same manner as in Example 1, and a sample of a light-emitting element according to Example 2 was created.

### Comparative Example 3

A sample of a light-emitting element according to Comparative Example 1 was prepared in the same manner as in Example 1 with the exception that the liquid containing octadecyltrimethoxysilane was not applied onto the hole transport layer.

### Comparative Example 4

A sample of a light-emitting element according to Comparative Example 2 was prepared in the same manner as in Example 1 with the exception that 3-aminopropyitrimethoxysilane (available from JNC Corporation) was used instead of octadecyltrimethoxysilane.

### Evaluation

The samples of light-emitting elements prepared in Example 2, Comparative Example 3, and Comparative Example 4 were each subjected to I′L′L measurements, and the external quantum efficiency (EQE) was calculated from the results. As a result, it was found that a higher external quantum efficiency was achieved in Example 2 than in Comparative Examples 3 and 4.

### REFERENCE SIGNS LIST

1, 1a, 1b Light-emitting element
20 First electrode
30 Hole transport layer
40 Light-emitting layer
41 Quantum dot
41a Semiconductor particle
41b Ligand
50 Organic silicon compound layer
60 Electron transport layer
70 Second electrode

1. A light-emitting element comprising:
a light-emitting layer including quantum dots;
an electron transport layer positioned on the light-emitting layer and containing metal oxide particles; and
an organic silicon compound including at least one hydrocarbon group and positioned between the light-emitting layer and the electron transport layer.

2. A light-emitting element comprising:
a light-emitting layer including quantum dots;
an electron transport layer positioned on the light-emitting layer and containing a metal oxide; and
an organic silicon compound including at least one hydrocarbon group and positioned between the light-emitting layer and the electron transport layer.

3. The light-emitting element according to claim 1, further comprising:
an organic silicon compound layer containing the organic silicon compound.

4. The light-emitting element according to claim 3, further comprising:
a hole transport layer arranged on a side of the light-emitting layer opposite the electron transport layer,
wherein the organic silicon compound layer and the hole transport layer are isolated by the light-emitting layer.

5. The light-emitting element according to claim 4,
wherein the hole transport layer includes a metal oxide, and
the light-emitting element further includes an organic silicon compound including at least one hydrocarbon group and positioned between the light-emitting layer and the hole transport layer.

6. A light-emitting element comprising:
a light-emitting layer including quantum dots;
a hole transport layer positioned on the light-emitting layer and containing a metal oxide; and
an organic silicon compound including at least one hydrocarbon group and positioned between the light-emitting layer and the hole transport layer.

7. The light-emitting element according to claim 6, further comprising:
an organic silicon compound layer containing the organic silicon compound.

8. The light-emitting element according to claim 3,
wherein the organic silicon compound layer is configured by a plurality of island-shaped portions including the organic silicon compound.

9. The light-emitting element according to claim 3,
wherein a plurality of through-holes are formed in the organic silicon compound layer.

10. The light-emitting element according to claim 3,
wherein the organic silicon compound layer includes a relatively thick portion and a relatively thin portion.

11. The light-emitting element according to claim 3,
wherein the organic silicon compound layer covers 100% of a surface of the hole transport layer.

12. The light-emitting element according to claim 1,
wherein a central portion in a thickness direction of the light-emitting layer does not contain the organic silicon compound.

13. The light-emitting element according to claim 12,
wherein the light-emitting layer does not contain the organic silicon compound.

14. The light-emitting element according to claim 1,
wherein four functional groups bonded to Si in the organic silicon compound are each an organic group.

15. The light-emitting element according to claim 1,
wherein the four functional groups bonded to Si in the organic silicon compound include a saturated or unsaturated hydrocarbon group having from 1 to 30 carbons.

16. The light-emitting element according to claim 1,
wherein the four functional groups bonded to Si in the organic silicon compound include a chain hydrocarbon group.

17. The light-emitting element according to claim 1,
wherein the four functional groups bonded to Si in the organic silicon compound include at least one of an alkoxyl group and an acetyl group.

18. The light-emitting element according to claim 1,
wherein one of the four functional groups bonded to Si in the organic silicon compound is a hydrocarbon group, and
the other three functional groups are each an alkoxyl group or an acetyl group.

19. The light-emitting element according to claim 1,
wherein the quantum dot includes
a semiconductor particle, and
a ligand positioned on an outer side of the semiconductor particle.

20.-24. (canceled)

25. The light-emitting element according to claim 1,
wherein an energy level of a lower end of a conduction band of the metal oxide included in the metal oxide particles is less than or equal to an energy level of a lower end of a conduction band of the quantum dots.

26. (canceled)

27. (canceled)
